(19) United States
(12) Patent Application Publication
(10) Pub. No.: US 2010/0047581 A1
(43) Pub. Date: Feb. 25, 2010

(54) ACTIN FILAMENT ASSOCIATED NANODEVICES

(76) Inventors: Seunghun Hong, Seoul (KR); Kyung-Eun Byun, Gyeonggi-do (KR)

Correspondence Address: Seunghun Hong, Asia Seonsuchon Apt. 6-205, Jamsil 7 dong, Songpa-gu, Seoul, 138-797, KR

(21) Appl. No.: 12/197,725

(22) Filed: Aug. 25, 2008

(51) Int. Cl. B32B 9/00; G03F 7/20; B05D 5/00

(52) U.S. Cl. 428/408; 430/322; 427/258; 977/700; 977/742

(57) ABSTRACT

Techniques for assembling actin filaments on a substrate and nanodevices including actin filaments are provided.

### BACKGROUND

The present disclosure relates generally to the field of nanotechnology. Recently, nanotechnology has found widespread use in various fields. For example, nanotechnology is being used to build machines at a microscopic level and to construct nanoscale chips implanted in a human body. Further, some medical nanodevices may need the mobility to swim through blood or a body tissue or need power to accomplish specific tasks, such as injection of a medication into a patient's blood or transportation of chemical agents to a target cell. Typically, batteries are not a good option to use in the nanoscale world, since, as the size of the device is scaled down, the battery size scales down to ˜R³. In the case of a mechanical system, since the energy consumption is generally caused by friction which is related to surface area, the energy consumption rates scales down to ˜R². Since the battery size is ˜R³, the lifetime of the battery, i.e., stored energy (˜R³; unit: J) divided by energy consumption rate (˜R²; unit: J/sec), is ˜R (unit: sec). For example, a common battery for a laptop computer (R˜10 cm) usually lasts for 10,000 seconds. Thus, if a 10 nm size battery with a similar efficiency to that of a laptop battery is considered, it will last for only 0.001 seconds, which is too short to provide locomotive forces to power nanodevices.

### SUMMARY

Various embodiments of methods for assembling actin filaments on a substrate are disclosed herein. In accordance with one aspect by way of non-limiting example, a method for assembling actin filaments on a substrate may involve: providing a substrate; patterning molecular regions on the substrate; forming carboxyl terminal regions on the substrate patterned with molecular regions; and adding actin filaments to the substrate having carboxyl terminal regions under conditions effective to allow the assembly of the actin filaments on the substrate.

In another aspect, the present disclosure provides a substrate having an assembly of actin filaments manufactured by the above method.

In another aspect, the present disclosure provides a nanodevice including a plurality of actin filaments assembled on a substrate, where the plurality of actin filaments are associated with the substrate via a carboxyl linkage.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIGS. 1A-C are schematic diagrams illustrating how myosin moves along actin filaments assembled on a substrate.

FIGS. 2A-B are schematic diagrams of an illustrative embodiment of a method for assembling actin filaments on a substrate.

FIGS. 3A-C are schematic diagrams of an illustrative embodiment of a method for forming carboxyl terminal regions on a substrate.

FIG. 4 shows an illustrative embodiment of a nano-actuator, including an assembly of actin filaments associated with a substrate.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. It will be readily understood that the components and methods of the present disclosure may be arranged and designed in a wide variety of different configurations, or performed in different sequences and/or repetitively. Other embodiments may be utilized, and other changes may be made, without departing from the spirit or scope of the subject matter presented here.

In one aspect, methods to use adenosine triphosphate (ATP) as an energy source in nanodevices include assembling motor proteins onto specific locations of solid structures to build engine structures. As described herein, motor proteins, which generate force and motion in biological systems by hydrolyzing ATP as a fuel, may be used as a component in nanoscale mechanical systems, due to their small dimensions and high fuel efficiency. ATP transports chemical energy within the cells for metabolism and is a major energy source for animals including humans.

For example, our muscles are made up of millions of proteins that are tiny molecular motors, which are biological molecular machines that are the essential agents of movement in living organisms. Many protein-based molecular motors harness the chemical free energy released by the hydrolysis of ATP in order to perform mechanical work in vivo. With this operation, for example, proteins called myosin, which are arranged in a regular pattern, can work together to produce forces and movement and walk along actin filaments, which is the origin of our muscle motion.

In some embodiments, motor proteins such as, but not limited to, actomyosin are assembled onto specific locations of solid structures to build engine structures. Actomyosin is composed of actin and myosin.

Actin is a small globular protein abundant in animal cells. Actin molecules each bind an ATP molecule and self-assemble into long, two-stranded filaments, during which the ATP is hydrolyzed into ADP. That is, actin filaments are filamentous structures formed of a polymer of the protein actin and a number of associated proteins. An actin filament is a major component of the contractile apparatus of skeletal muscle and comprises polymerized globular actin molecules. Actin filaments are highly similar among species and typically have approximately a 10 nm diameter, a 2.77 nm rise, and 26 subunits/74 nm repeat; however, actin filaments from any other species and/or sources, e.g., rabbit skeletal muscle cells, bovine cardiac muscle cells, and human platelets, may be used. In one embodiment by way of non-limiting example, actin may be prepared from an acetone powder of rabbit skeletal muscle, using the method described by Spudich, J. A., and S. Watt, “The Regulation of Rabbit Skeletal Muscle Contraction. I. Biochemical Studies of the Interaction of the Tropomyosin-Troponin Complex with Actin and the Proteolytic Fragments of Myosin,” J. Biol. Chem. 246:4866-4871 (1971). In other embodiments, actins prepared by various other methods, e.g., genetically engineered actins, recombinant actins, or various other modified actins, may be used. Alternatively, actin may be purchased from commercial sources, e.g., Cytoskeleton Inc. (Denver, Colo.).

Myosin is a large elastic fibrous protein, and is a member of the family of motor ATPases that interact with actin filaments. Typically, myosin molecules have a head and a tail. The head binds to the actin filament and uses ATP hydrolysis to generate force and move along the filament, while the tail mediates interaction with cargo molecules and/or other myosin subunits. Myosin may be extracted from the muscle or non-muscle cells of various species using the method described in Margossian, S. S. and S. Lowey, “Preparation of Myosin and Its Subfragments From Rabbit Skeletal Muscle,” Methods Enzymol. 85:55-71 (1982). Those skilled in the art, however, will appreciate that myosin obtained by other methods, e.g., genetically engineered myosins, and various other modified myosins, may also be used. Alternatively, myosin may be purchased from commercial sources, e.g., Cytoskeleton Inc.

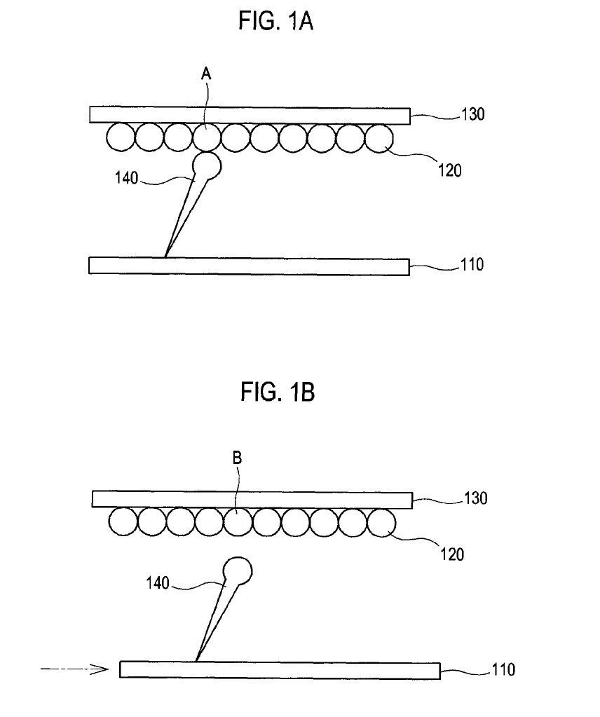

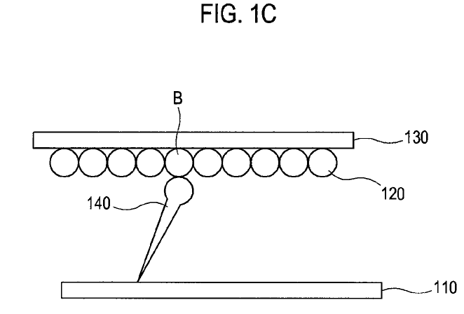

Although not wishing to be limited by a mechanistic description, FIGS. 1A-C provide schematic diagrams illustrating how myosin moves along actin filaments assembled on a substrate. Specifically, as illustrated in FIG. 1A, the head 140 of the myosin 110 first binds to the actin filament 120 (depicted as a chain of beads), formed on a substrate 130 at position “A,” bridging the gap between the actin filament 120 and the myosin 110. Next, one molecule of ATP reacts with the myosin 110 to release energy and cause a change in the conformation of the myosin 110, resulting in the myosin head 140 pulling on the actin filament 120. Then, as illustrated in FIG. 1B, the myosin 110 releases the myosin head 140 from the actin filament 120, where the head 140 is ready to bind to a new position “B” on the actin filament 120. Next, the myosin head 140 binds to the actin filament 120 at position “B,” bridging the gap between the actin filament 120 and the myosin 110. Then, one molecule of ATP reacts with the myosin 110 again. By repeating this cycle, the myosin 110 is able to move or “walk” along the actin filament 120.

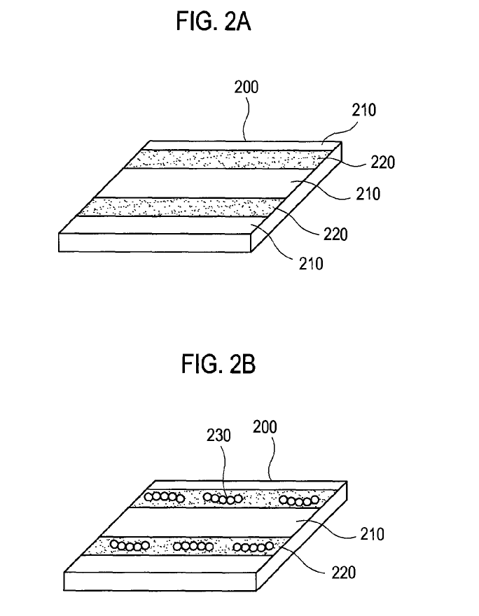

FIGS. 2A-B provide schematic diagrams of an illustrative method for assembling actin filaments on a substrate. Those of ordinary skill will appreciate that, for this and other processes and methods disclosed herein, the functions performed in the processes and methods may be implemented in differing order as well as repetitively, for example. Furthermore, the outlined steps are provided only as examples, and some of the steps may be optional, combined into fewer steps, or expanded to include additional steps without detracting from the essence of the present disclosure.

First, a substrate 200, on which the actin filaments are to be assembled, is provided. By way of example, but not limitation, the substrate 200 may be made of gold, oxide, silicon, quartz, and silicon nitride. Those skilled in the art will appreciate that any kind of substrate may be used for the methods disclosed herein as long as molecular regions can be patterned on the substrate. The approximate dimensions of the substrate 200 may range from about 0.5 cm to about 20 cm in length or width, depending on what the final actin filament assembly is being used for. In some embodiments, the dimensions of the substrate 200 may range from about 1 cm to about 20 cm, from about 2 cm to about 20 cm, from about cm to about 20 cm, from about 7.5 cm to about 20 cm, from about 10 cm to about 20 cm, from about 15 cm to about 20 cm, from about 0.5 cm to about 1 cm, from about 0.5 cm to about 2 cm, from about 0.5 cm to about 5 cm, from about 0.5 cm to about 7.5 cm, from about 0.5 cm to about 10 cm, from about 0.5 cm to about 15 cm, from about 1 cm to about 2 cm, from about 2 cm to about 5 cm, from about 5 cm to about 7.5 cm, from about 7.5 cm to about cm, or from about 10 cm to about 15 cm, in length or width. In other embodiments, the substrate 200 may be about 0.5 cm, about 1 cm, about 2 cm, about 5.0 cm, about 7.5 cm, about 10 cm, about 15 cm, or about 20 cm.

As illustrated in FIG. 2A, molecular patterns comprising neutral regions 210 and carboxyl terminal regions 220 are formed on the surface of the substrate. The dimension or design of the molecular patterns may vary widely depending on the desired dimension or design of the final actin filament assembly. In one embodiment by way of non-limiting example, the molecular pattern may be a striped pattern, as illustrated in FIG. 2A. In other embodiments, other patterns with different designs may also be used without limitation. The width of one stripe in the pattern illustrated in FIG. 2A may range from about 1 μm and about 20 μm, although the width may be even smaller depending on the dimension of the substrate on which the pattern is being formed. In some embodiments, the width may range from about 4 μm to about 20 μm, from about 8 μm to about 20 μm, from about 12 μm to about 20 μm, from about 16 μm to about 20 μm, from about 1 μm to about 4 μm, from about 1 μm to about 8 μm, from about 1 μm to about 12 μm, from about 1 μm to about 16 μm, from about 4 μm to 8 μm, from about 8 μm to about 12 μm, or from about 12 μm to about 16 μm. In other embodiments, the width may be about 1 μm, about 4 μm, about 8 μm, about 12 μm, about 16 μm, or about 20 μm.

In some embodiments, the molecular patterns are formed on the substrate using, among other methods, self-assembled monolayer (SAM) patterning, for example. A SAM is a single layer of molecules on a substrate. Generally, in order to form a SAM, the substrate is immersed in a dilute solution of film molecules whereby a monolayer film forms in a time ranging from a few minutes to a few hours. Various chemically functionalized materials can be prepared by varying the terminal group of the self-assembling monolayer. The driving force for surface aggregation and self-assembly is: (i) a covalent bond formation of the SAM molecules with the substrate surface via suitable functional groups and (ii) intermolecular, van der Waals-type interactions between the hydrocarbon chains of the SAM molecules.

In some embodiments, the SAM patterning method may include microcontact printing. Microcontact printing uses an elastomeric stamp to deposit molecules on surfaces. An apparatus for microcontact printing may comprise a stamp assembly having a stamp, an actuator that actuates movement between the stamp and a print surface, and a control system that controls movement of the stamp and the print surface. Thus, the stamp is inked with a solution of molecules, which will coat the stamp. The stamp is pressed onto the surface to be patterned for a predetermined time, e.g., from about 3 seconds to about 15 seconds, where the stamp makes contact with the surface and the molecules are transferred from the stamp to the surface. In some embodiments, the stamp may be pressed onto the surface to be patterned for about 5 seconds to about 15 seconds, about 10 seconds to about 15 seconds, about 3 seconds to about 5 seconds, about 3 seconds to about 10 seconds, or for about 5 seconds to about 10 seconds. In other embodiments, the stamp may be pressed onto the surface to be patterned for about 3 seconds, about 5 seconds, about 10 seconds, or about 15 seconds.

In some embodiments, the SAM patterning method may include photolithography. Photolithography is a process used in microfabrication to selectively remove parts of a thin film by using light to transfer a geometric pattern from a photomask to a light-sensitive chemical on the substrate. A photolithography device may comprise an illumination system having a light emitting source and a rotating projection unit, and an imaging system for imaging the illuminated spot of the pattern plane onto a substrate. In one embodiment by way of non-limiting example, a pattern may be formed on the substrate by photoresist and then the substrate may be immersed in a solution of molecules which will coat the substrate for about 5 minutes to about 15 minutes at above 70% humidity. In some embodiments, the substrate may be immersed in the solution of molecules for about 8 minutes to about 15 minutes, about 11 minutes to about 15 minutes, about 5 minutes to about 8 minutes, about 5 minutes to about 11 minutes, or about 8 minutes to about 11 minutes. In other embodiments, the substrate may be immersed in the solution of molecules for about 5 minutes, about 8 minutes, about 11 minutes, or about 15 minutes.

Referring to FIG. 2A, neutral or nonpolar regions 210 are patterned on the surface of a substrate 200. In one embodiment, neutral or nonpolar regions 210 may be formed on the substrate 200 by SAM-patterning the surface of the substrate 200 with neutral or nonpolar molecules. When atoms in a molecule have different electronegativity, which refers to the tendency of a nucleus to hold electrons, the molecule may have a polar property. The relative electronegativity for typical atoms in a molecule is as follows: O>N>S>C≈H. Accordingly, since C and H have similar electronegativities, bonding electrons are more or less evenly distributed in hydrocarbon regions. On the other hand, in bonds such as C═O or O—H, since O is more electronegative than C and H, the electrons tend to shift towards the electronegative O atom. Therefore, C═O and O—H may give the molecule a polar property, whereas C—C and C—H may provide the molecule with a nonpolar property.

The neutral or nonpolar molecules used for the SAM patterning may be varied depending on the composition of the substrate 200. For example, the neutral or nonpolar regions 210 may be a SAM comprised of 1-octadecanethiol (ODT) for a gold substrate surface or a SAM comprised of octadecyltrichlorosilane (OTS) for an oxide surface. ODT is an organosulfur compound, where the thiol- or sulfur-containing portion of the compound has an affinity for gold or other noble metals, such as palladium, platinum, and silver, and chemically bonds to the metal surface. The affinity of the thiol- or sulfur-containing portion of ODT chemically bonding with the metal, e.g., gold, allows ODT to attach to the metal surface relatively strongly. OTS is an organometallic compound and is used in the semiconductor industry to form self-assembled monolayer thin films on oxide substrates. OTS has a silane group, which has a high affinity for oxide, and thus, easily attaches to oxides. Both ODT and OTS have the nonpolar —CH₃ as the terminal group.

The neutral ODT and OTS SAM patterns may be formed on the substrate by various methods including, but not limited to, microcontact printing and photolithography, already described above. Although ODT and OTS are described above as molecules for forming the neutral or nonpolar regions 210 on the substrate 200, other molecules may also be used without limitation in other embodiments as long as they can create neutral regions on a substrate by reacting with the specific substrate.

Referring again to FIG. 2A, carboxyl terminal regions 220 are formed on the surface of the substrate 200. A carboxyl group (also called a carboxy group) is a functional group present in organic molecules, such as amino acids and carboxylic acids. A carboxyl group is composed of one carbon atom attached to an oxygen atom by a double bond and to a hydroxyl group by a single bond. One valence electron on the carbon is available for bonding to another atom so that the carboxyl group can form part of a larger molecule. The carboxyl terminal regions 220 may be formed on regions of the substrate 200 where the neutral or nonpolar regions 210 have not been formed using photolithography techniques to cover the neutral or nonpolar regions 210 with a photomask and then forming SAM molecules having carboxyl groups on the substrate 200. In other embodiments, the carboxyl terminal regions 220 may be formed on regions of the substrate 200 where the neutral or nonpolar regions 210 have not been formed using microcontact printing techniques to transfer molecules having carboxyl groups from a stamp to those regions of the substrate 200.

In one embodiment, the substrate 200 is an oxide substrate, where the specific regions expected to become the carboxyl terminal regions 220 of the substrate 200 are functionalized with carboxyl (—COOH) groups, by patterning 16-mercaptohexadecanoic acid (HS—C₁₅H₃₀—COOH; 16-MHDA) self-assembled monolayers (SAMs) for example, on the substrate 200. Such carboxyl group-containing SAMs can be applied on top of the substrate 200 that already has the neutral or nonpolar regions 210 without damaging the neutral or nonpolar regions 210, since the thiol-containing portions of the neutral molecules, e.g., ODT, for forming the neutral regions 210 are already bound to the metal substrate 200, thus leaving none of the thiol-containing portions of the neutral or nonpolar region 210 available for functionalization with the carboxyl groups.

A variety of other compounds, e.g., HS—(CH₂)ₘ—COOH, where m=10 or 11 but not limited thereto, may be used as long as they can functionalize the substrate 200 with carboxyl groups to form carboxyl terminal regions 220. For example, suitable compounds include, but are not limited to: methanoic acid, ethanoic acid, propanoic acid, butanoic acid, pentanoic acid, hexanoic acid, heptanoic acid, octanoic acid, nonanoic acid, decanoic acid, dodecanoic acid, hexadecanoic acid, octadecanoic acid, acrylic acid, docosahexaenoic acid, eicosapentaenoic acid, amino acids, pyruvic acid, acetoacetic acid, benzoic acid, salicylic acid, aldaric acid, oxalic acid, malonic acid, malic acid, succinic acid, glutaric acid, adipic acid, citric acid, isocitric acid, aconitic acid, propane-1,2,3-tricarboxylic acid, and lactic acid.

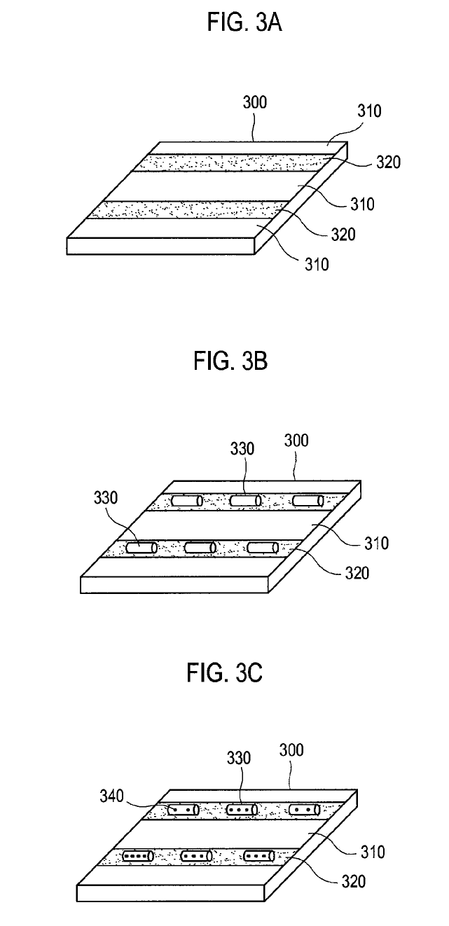

In another embodiment, carboxyl terminal regions 320 may be formed on a substrate 300 by patterning carbon nanostructures 330, such as carbon nanotubes, on the substrate 300, introducing defects 340 on the carbon nanostructures 330, and creating carboxyl groups on the nanostructure defects 340, as illustrated in FIGS. 3A-C. Carbon nanotubes are an array of carbon atoms having the shape of a two-dimensional graphene sheet rolled into a tube, which are useful in many nanotechnology applications due to unique nanostructures with remarkable electronic and mechanical properties. The electronic properties of carbon nanotubes depend on the diameter and chirality of the carbon nanotubes. However, certain defects in the carbon nanotube, i.e., where a single carbon atom in the nanotube is missing or has been replaced by another atom, can drastically modify the electronic properties of the carbon nanotube. Thus, the introduction of defects in carbon nanotubes is one way to modify the intrinsic properties of the carbon nanotubes and create carboxyl groups on the carbon nanotubes.

As illustrated in FIG. 3A, the neutral regions 310 and the regions 320 onto which carbon nanotubes are to be adsorbed may be formed on the substrate 300 by first patterning a plurality of molecular regions on the substrate 300. In some embodiments, the neutral or nonpolar regions 310 may be formed on the substrate 300 by SAM-patterning the surface of the substrate 300 with neutral molecules, e.g., ODT and OTS, similar to the above described method for forming neutral or nonpolar regions 210 on the substrate 200. In some embodiments, the regions 320 onto which carbon nanotubes are to be adsorbed may be formed on the substrate 300 by patterning SAM molecules having polar groups on the substrate 300, similar to the above described method for forming carboxyl terminal regions 210 on the substrate 200. Since carbon nanotubes are adsorbed to polar molecules, polar molecular regions may be formed on the substrate 300 as the regions 320 onto which carbon nanotubes are to be adsorbed.

Next, as illustrated in FIG. 3B, carbon nanotubes 330 are adsorbed onto specific regions on the substrate 300, e.g., the polar regions 320, utilizing the difference in adsorption properties of the different molecular regions with respect to the carbon nanotubes 330. In some embodiments, the carbon nanotubes 330 may be patterned on the substrate by using linker molecules between the nanotubes 330 and the surface of the substrate 300. Using the above method, the carbon nanotubes 330 can be assembled according to the specific molecular pattern on the substrate.

Then, as illustrated in FIG. 3C, defects may be introduced in the assembled carbon nanotubes 330 and carboxyl groups 340 are formed on the nanotube defects. In some embodiments, the defects are introduced in the carbon nanotubes 330 and the carboxyl groups 340 are formed on such defects by subjecting the nanotubes 330 to plasma cleaning, using a plasma cleaner which removes atoms from the surface of the nanotubes 330 through an energetic plasma created from gaseous species, as described in S. Lu and B. Panchapakesan, “Nanotube Micro-Optomechanical Actuators,” Appl. Phys. Lett. 88:253107 (2006). More defects may be generated in the carbon nanotubes 330 by carrying out the plasma cleaning for a longer time; however, the plasma cleaning time should be controlled to prevent the burning of the carbon nanotubes 330. In some embodiments, the plasma cleaning time may range from about 5 minutes to about 8 minutes, from about 6 minutes to about 8 minutes, from about 7 minutes to about 8 minutes, from about 5 minutes to about 6 minutes, from about 5 minutes to about 7 minutes, or from about 6 minutes to about 7 minutes. In other embodiments, the plasma cleaning time may be about 5 minutes, about 6 minutes, about 7 minutes, or about 8 minutes. In other embodiments, the defects are introduced in the carbon nanotubes 330 and the carboxyl groups 340 are formed on such defects by reacting the carbon nanotubes 330 with an acid, such as but not limited to, sulfuric acid and nitric acid, as described in Zhao et al., “Water-Soluble and Optically pH-Sensitive Single-Walled Carbon Nanotubes from Surface Modification,” J. Am. Chem. Soc. 124:12418-12419 (2002).

While the two above methods are described for functionalizing the surface of a substrate with carboxyl groups, any other method may be used as long as it is capable of creating carboxyl terminal regions on the substrate.

Referring back to FIG. 2B, actin filaments 230 are assembled on the carboxyl terminal regions 220 of the substrate 200 via a carboxyl linkage. In one embodiment, the substrate 200 is placed in a solution of actin filaments 230 under conditions effective to allow the assembly of the actin filaments on the carboxyl terminal regions 220. In some embodiments, the actin filament concentration in the solution may range from about 0.005 mg/ml to about 0.1 mg/ml, from about 0.01 mg/ml to about 0.1 mg/ml, from about 0.04 mg/ml to about 0.1 mg/ml, from about 0.07 mg/ml to about 0.1 mg/ml, from about 0.005 mg/ml to about 0.01 mg/ml, from about 0.005 mg/ml to about 0.04 mg/ml, from about 0.005 mg/ml to about 0.07 mg/ml, from about 0.01 mg/ml to about 0.04 mg/ml, or from about 0.04 mg/ml to about 0.07 mg/ml. In other embodiments, the actin filament concentration in the solution may be about 0.005 mg/ml, about 0.01 mg/ml, about 0.04 mg/ml, about 0.07 mg/ml, or about 0.1 mg/ml. In one embodiment by way of non-limiting example, the solution of actin filaments may include 50 mM imidazol-HCl at pH 7, 50 mM KCl, 8 mM MgCl₂, and 2 mM EGTA at pH 7.

Actin is known to bind to carboxyl groups with a high affinity, which is why the above actin filaments 230 are assembled on the carboxyl terminal regions 220 rather than on the neutral regions 210. In some embodiments, the substrate 200 may be placed in the actin filament solution for a predetermined time, such as but not limited to, about 30 minutes or about 1 hour. In some embodiments, the predetermined time may range from about 35 minutes to about 1 hour, from about 40 minutes to about 1 hour, from about 45 minutes to about 1 hour, from about 50 minutes to about 1 hour, from about 55 minutes to about 1 hour, from about 30 minutes to about 35 minutes, from about 30 minutes to about 40 minutes, from about 30 minutes to about 45 minutes, from about 30 minutes to about 50 minutes, from about 30 minutes to about 55 minutes, from about 35 minutes to about 40 minutes, from about 40 minutes to about 45 minutes, from about 45 minutes to about 50 minutes, or from about 50 minutes to about 55 minutes. In other embodiments, the predetermined time may be about 30 minutes, about 35 minutes, about 40 minutes, about 45 minutes, about 50 minutes, about 55 minutes, or about 1 hour. Then, the actin filaments 230 are selectively adsorbed onto the carboxyl terminal regions 220. Optionally, the substrate 200 may be washed in order to remove the actin filaments that did not attach to the substrate 200. In some embodiments, the above method may be carried out at room temperature.

By using the above illustrative embodiments disclosed herein, actin filaments can be selectively assembled on solid substrates with the desired orientation, whereby the actin filaments assembled on the substrate can be used as a track so that myosin motors can deliver nanostructures along specific directions.

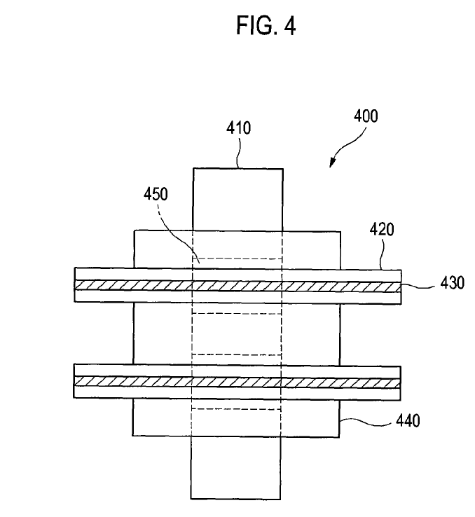

FIG. 4 shows an illustrative example of a nano-actuator including a substrate having an assembly of actin filaments. The nano-actuator 400 includes a nano-rod 410, an actin track 420 patterned with actin filaments 430, and a well 440 containing ATP. In some embodiments, the nano-rod 410 may be made of a metal selected from the group consisting of nickel, palladium, platinum, gold, cobalt, permalloy, chromium, and any mixture thereof. The nano-rod 410 may have a length ranging from about 100 nm to about 100 μm. In some embodiments, the length of the nano-rod 410 may range from about 1 μm to about 100 μm, from about 20 μm to about 100 μm, from about 40 μm to about 100 μm, from about 60 μm to about 100 μm, from about 80 μm to about 100 μm, from about 100 nm to about 1 μm, from about 100 nm to about 20 μm, from about 100 nm to about 40 μm, from about 100 nm to about 60 μm, from about 100 nm to about 80 μm, from about 1 μm to about 20 μm, from about 20 μm to about 40 μm, from about 40 μm to about 60 μm, or from about 60 μm to about 80 μm. In other embodiments, the length may be about 100 nm, about 1 μm, about 20 μm, about 40 μm, about 60 μm, about 80 μm, or about 100 μm. Further, the nano-rod 410 may have a diameter ranging from about 20 nm to about 200 nm. In some embodiments, the diameter of the nano-rod 410 may range from about 50 nm to about 200 nm, from about 80 nm to about 200 nm, from about 110 nm to about 200 nm, from about 140 nm to about 200 nm, from about 170 nm to about 200 nm, from about 20 nm to about 50 nm, from about 20 nm to about 80 nm, from about 20 nm to about 110 nm, from about 20 nm to 140 nm, from about 20 nm to about 170 nm, from about 50 to about 80 nm, from about 80 to about 110 nm, from about 110 to about 140, or from about 140 to about 170 nm. In other embodiments, the diameter may be about 20 nm, about 50 nm, about 80 nm, about 110 nm, about 140 nm, about 170 nm, or about 200 nm.

The nano-rod 410 may have a biocompatible molecular layer deposited on its surface, onto which a myosin coating portion 450 is formed so that the nano-rod 410 can move substantially linearly as a result of the biomolecular interaction between the actin filaments 430 on the actin track 420 and the myosin coating portion 450. In some embodiments, the biocompatible molecular layer may include, but are not limited to, OTS or 3-(2-aminoethylamino) propyltrimethoxysilane. The biocompatible molecular layer may be deposited on the nano-rod 410 by any technique, including but not limited to dip-pen nanolithography, and promotes the attachment of myosin. Myosin 450 can be assembled on the biocompatible molecular layer of the nano-rod 410 via direct chemical binding to the biocompatible molecular layer.

The ATP well 440 holds ATPs to aid in the interaction between the myosin on the myosin coating portion 450 and the actin filaments 430 on the actin track 420. In some embodiments, the ATP well 440 may be a reservoir holding an ATP solution and having two orifices positioned opposite each other which are suitable for receiving the nano-rod 410. The nano-rod 410 is capable of slidingly moving through the two orifices of the reservoir, while the actin track 420 may be positioned on the inside surface of the ATP well 440.

In some embodiments, the actin filaments 430 on the actin track 420 are parallel to the longitudinal axis of the nano-rod 410. As described above, myosin, the motor protein, consumes ATP as fuel to walk along the actin track 420. Thus, the nano-rod 410 having the myosin coating portion 450 would slide up and down due to the interaction with the actin filaments 430 on the actin track 420 and will move along the longitudinal axis of the nano-rod 410.

Nano-devices having one or more nano-actuators as described herein, have various nano-mechanical applications. For example, the method described in the present disclosure may be used to manufacture bioenergy generators, which include a biomolecular portion, such as the exemplary nano-actuator described above, and an electric generator portion for producing electricity. For example, a nano-rod having a coil may rotate in a magnetic field in order to induce current in the coil, where the current may be used to power nanodevices.

### EQUIVALENTS

The present disclosure is not to be limited in terms of the particular embodiments described in this application. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, or compositions, which can, of course, vary. It is also to be understood that the terminology used herein is for the purpose of describing particular embodiments only, and is not intended to be limiting.

Those skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A method for assembling actin filaments on a substrate, said method comprising:
providing a substrate;
patterning molecular regions on said substrate;
forming carboxyl terminal regions on said substrate patterned with molecular regions; and
adding actin filaments to said substrate having carboxyl terminal regions under conditions effective to allow the assembly of the actin filaments on the substrate.

2. The method of claim 1, wherein said substrate is selected from the group consisting of gold, oxide, silicon, quartz, and silicon nitride.

3. The method of claim 1, wherein said patterning molecular regions on the substrate comprises patterning neutral molecular regions on the substrate.

4. The method of claim 3, wherein said patterning neutral molecular regions on the substrate comprises patterning a self-assembled monolayer.

5. The method of claim 4, wherein said patterning a self-assembled monolayer is carried out by microcontact printing or photolithography.

6. The method of claim 4, wherein said substrate is a gold substrate and said self-assembled monolayer comprises 1-octadecanethiol.

7. The method of claim 4, wherein the substrate is an oxide substrate and said self-assembled monolayer comprises octadecyltrichlorosilane.

8. The method of claim 1, wherein said forming carboxyl terminal regions on the substrate comprises patterning a self-assembled monolayer of molecules having carboxyl groups.

9. The method of claim 8, wherein said molecule having carboxyl groups is a compound selected from the group consisting of: 16-mercaptohexadecanoic acid, methanoic acid, ethanoic acid, propanoic acid, butanoic acid, pentanoic acid, hexanoic acid, heptanoic acid, octanoic acid, nonanoic acid, decanoic acid, dodecanoic acid, hexadecanoic acid, octadecanoic acid, acrylic acid, docosahexaenoic acid, eicosapentaenoic acid, amino acids, pyruvic acid, acetoacetic acid, benzoic acid, salicylic acid, aldaric acid, oxalic acid, malonic acid, malic acid, succinic acid, glutaric acid, adipic acid, citric acid, isocitric acid, aconitic acid, propane-1,2,3-tricarboxylic acid, and lactic acid.

10. The method of claim 1, wherein said forming carboxyl terminal regions on the substrate comprises patterning carbon nanostructures on the substrate and introducing defects in the carbon nanostructures under conditions effective to create carboxyl groups on the carbon nanostructures.

11. The method of claim 10, further comprising patterning a plurality of molecular regions on the substrate, prior to said patterning carbon nanostructures on the substrate.

12. The method of claim 10, wherein said carbon nanostructures are carbon nanotubes.

13. The method of claim 10, wherein said introducing the defects in the carbon nanostructures is carried out by adding acid to the carbon nanostructures.

14. The method of claim 10, wherein said introducing the defects in the carbon nanostructures is carried out by adding a substance to the carbon nanostructures that is capable of removing atoms from the surface of the nanostructures.

15. The method of claim 1, wherein said adding actin filaments to the substrate having carboxyl terminal regions comprises placing the substrate in a solution containing actin filaments.

16. A substrate having an assembly of actin filaments manufactured by the method of claim 1.

17. A nanodevice comprising:
a plurality of actin filaments assembled on a substrate,
wherein the plurality of actin filaments are associated with the substrate via a carboxyl linkage.

18. The nanodevice of claim 17, wherein the substrate comprises at least one region of a self-assembled monolayer of molecules having carboxyl groups.

19. The nanodevice of claim 17, wherein the substrate comprises at least one region of carbon nanostructures having carboxyl groups.
